(19) United States
(12) Patent Application Publication
(10) Pub. No.: US 2026/0206560 A1
(43) Pub. Date: Jul. 16, 2026

(54) SEMICONDUCTOR STRUCTURE AND METHOD FOR MANUFACTURING THE SAME

(71) Applicant: MACRONIX INTERNATIONAL CO., LTD., Hsinchu (TW)

(72) Inventors: Erh-Kun LAI, Taichung County (TW); Hsiang-Lan LUNG, Kaohsiung City (TW)

(21) Appl. No.: 19/015,981

(22) Filed: Jan. 10, 2025

(51) Int. Cl. H01L 21/768; H01L 23/528; H01L 23/535

(52) U.S. Cl. CPC H10W 20/0698; H10W 20/076; H10W 20/083; H10W 20/089; H10W 20/20; H10W 20/435

(57) ABSTRACT

A semiconductor structure and a method for manufacturing the same are provided. The semiconductor structure includes a staircase structure comprising conductive layers and insulating layers stacked alternately, a conductive pillar on the staircase structure and an insulating structure penetrating the staircase structure and connected to the conductive pillar.

### BACKGROUND

### Technical Field

The disclosure relates to a semiconductor structure and a method for manufacturing the same, and more particularly to a three-dimensional semiconductor structure and a method for manufacturing the same.

### Description of the Related Art

As the size of semiconductor structures shrinks, formation of interconnection structures, such as conductive pillars, in semiconductor structures becomes more difficult. For example, the shrinkage of the semiconductor structure will reduce the thickness of the conductive layer in the semiconductor structure; the thin conductive layer will make it difficult for the etching process used to form the interconnection structure to stop on the target conductive layer (e.g. over-etching); over-etching of the interconnection structure may cause the interconnect structure to electrically connect to unintended conductive layer, resulting in reduced electrical performance of the semiconductor structure.

### SUMMARY

The disclosure provides a semiconductor structure and a method for manufacturing the same. The component configuration of the semiconductor structure and the method for manufacturing the same according to the present disclosure can avoid the problem of difficult control of etching, and can improve the electrical performance of the semiconductor structure.

According to embodiments of the present disclosure, a semiconductor structure is provided. The semiconductor device includes a staircase structure including conductive layers and insulating layers stacked alternately, a conductive pillar on the staircase structure, and an insulating structure penetrating the staircase structure and connected to the conductive pillar.

According to embodiments of the present disclosure, a method for manufacturing a semiconductor structure is provided. The method includes: forming a staircase structure, wherein the staircase structure includes conductive layers and insulating layers stacked alternately; forming an insulating structure penetrating the staircase structure; forming a conductive pillar on the staircase structure.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1 illustrates a schematic cross-sectional view of a semiconductor structure according to some embodiments of the present disclosure.

FIG. 1A illustrates a schematic top view of the semiconductor structure of FIG. 1.

FIG. 1B illustrates a schematic top view of the semiconductor structure of FIG. 1.

FIG. 2 to FIG. 9 illustrate schematic cross-sectional views of structures at various stages of a method for manufacturing a semiconductor structure according to some embodiments of the present disclosure.

### DETAILED DESCRIPTION

Various embodiments will be described more fully hereinafter with reference to accompanying drawings, which are provided for illustrative and explaining purposes rather than a limiting purpose. For clarity, the components may not be drawn to scale. In addition, some components and/or reference numerals may be omitted from some drawings. It is contemplated that the elements and features of one embodiment can be beneficially incorporated in another embodiment without further recitation. In the following methods for manufacturing semiconductor devices, there may be one or more additional operations between the operations described, and the order of the operations may vary. The illustration uses the same/similar reference numerals to indicate the same/similar elements.

As used in the specification and the appended claims, the ordinals such as “first”, “second” and the like to describe elements do not imply or represent a specific position in the structure, or the order of arrangement, or the order of manufacturing. The ordinals are only used to clearly distinguish multiple elements with the same name. As used in the specification and the appended claims, spatial relation terms such as “on”, “above”, “over”, “upper,” “top”, “below”, “beneath”, “under”, “lower”, “bottom” and the like may be used to describe the relative spatial relations or positional relations between one element(s) and another element(s) as illustrated in the drawings, and these spatial relations or positional relations, unless specified otherwise, can be direct or indirect. The spatial relation terms are intended to encompass different orientations of structures in addition to the orientation depicted in the drawings. The structure can be inverted or rotated by various angles, and the spatial relation descriptions used herein can be interpreted accordingly. As used in the specification and the appended claims, the singular forms “a,” “an,” and “the” are intended to include the plural forms as well, unless the context clearly indicates otherwise. As used in the specification and the appended claims, the term “and/or” includes any and all combinations of one or more of the associated listed items.

Additionally, the term “electrically connected” used in the specification and claims can refer to an ohmic contact between elements, or current passing through elements, or an operational relation between elements. The operational relation may mean, for example, that one element is used to drive another element, but current may not flow directly between these two elements. As used in the specification and the appended claims, term “adjoin” refers to “be adjacent to and contact”. As used in the specification and the appended claims, term “deposition” includes, but is not limited to, chemical vapor deposition (CVD), physical vapor deposition (PVD), atomic layer deposition (ALD) and epitaxial growth. Depending on the type of material to be formed, a person of ordinary skill in the art can select an appropriate technology for forming the material. As used in the specification and the appended claims, term “etching” includes, but are not limited to, dry etching and wet etching. As used in the specification and the appended claims, term “polishing process” includes, but is not limited to, a chemical-mechanical planarization (CMP) and an ion milling process. The terms “etching” and “polishing process” used in the specification and the appended claims may replace with each other, and a person of ordinary skill in the art can select an appropriate removal technology depending on the structure and material.

Embodiments according to the present disclosure can be applied to many different types of three-dimensional semiconductor structures. For example, the embodiments of the present disclosure can be applied to, but not limited to, three-dimensional NAND type memory devices, three-dimensional ovonic threshold switch (OTS) memory devices or any type of three-dimensional memory devices.

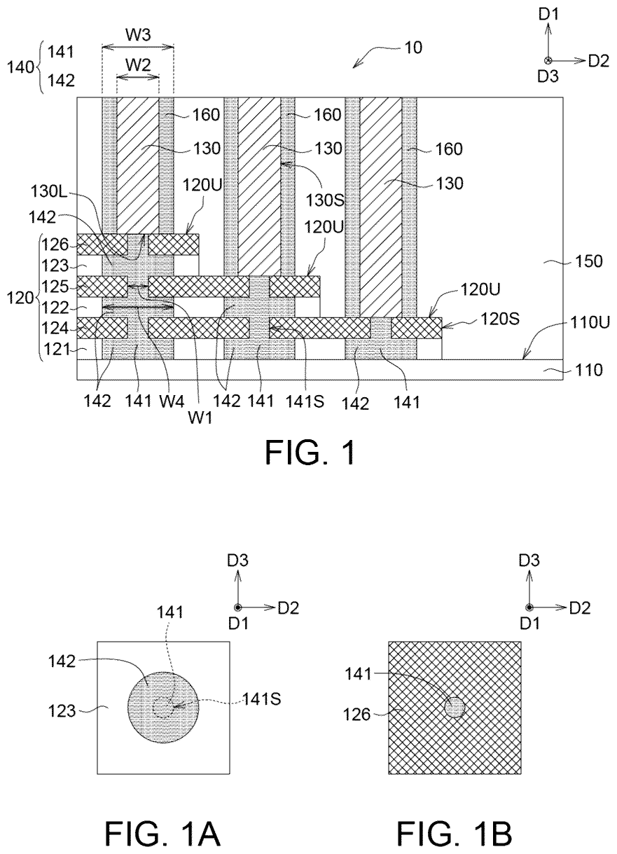

Referring to FIGS. 1, 1A and 1B, FIG. 1 illustrates a schematic cross-sectional view of a semiconductor structure 10 according to some embodiments of the present disclosure, FIG. 1A illustrates a schematic top view of the semiconductor structure 10 of FIG. 1, corresponding to a plane of an insulating layer 123, and FIG. 1B illustrates a schematic top view of the semiconductor structure 10 of FIG. 1, corresponding to a plane of a conductive layer 126. The semiconductor structure 10 includes a substrate 110, a staircase structure 120, one or more conductive pillars 130, one or more insulating structures 140, a dielectric structure 150 and one or more insulating films 160. The number of each element in the semiconductor structure 10 is not limited to the number shown in the drawings, and the number of each element in the semiconductor structure 10 can be adjusted according to actual needs.

The staircase structure 120 is disposed on an upper surface 110U of the substrate 110 along a first direction D1. The staircase structure 120 includes insulating layers 121~123 and conductive layers 124~126 stacked alternately along the first direction D1. The conductive layers 124~126 are separated from each other by the insulating layers 121~123. The insulating layers 121~123 and the conductive layers 124~126 can extend along a second direction D2 and a third direction D3. The insulating layers 121~123 have different sizes; the sizes of the insulating layers 121~123 are, for example, the areas on a plane formed by the second direction D2 and the third direction D3 (or can be understood as cross-sectional areas), or widths in the second direction D2 (or can be understood as lateral widths), or widths in the third direction D3 (or can be understood as lateral widths). The conductive layers 124~126 have different sizes; the sizes of the conductive layers 124~126 are, for example, the areas on a plane formed by the second direction D2 and the third direction D3 (or can be understood as cross-sectional areas), or widths in the second direction D2 (or can be understood as lateral widths), or widths in the third direction D3 (or can be understood as lateral widths). For example, the cross-sectional areas of the conductive layers 124~126 becomes smaller along the direction away from the substrate 110. For example, a cross-sectional area of the conductive layer 124 at a lower level (a level closer to the substrate 110) is larger than a cross-sectional area of the conductive layer 125 at an upper level (a level farther from the substrate 110).

For example, the first direction D1 is the normal direction of the upper surface 110U of the substrate 110. For example, the second direction D2 and the third direction D3 are directions parallel to the upper surface 110U of the substrate 110. The first direction D1, the second direction D2 and the third direction D3 are perpendicular to each other.

The dielectric structure 150 is on the substrate 110 and the staircase structure 120. The dielectric structure 150 may cover a portion of the upper surface 110U of the substrate 110, an upper surface 120U of the staircase structure 120 and a sidewall 120S of the staircase structure 120. In the present embodiment, the upper surface 120U of the staircase structure 120 includes an upper surface of the conductive layer 124, an upper surface of the conductive layer 125 and an upper surface of the conductive 126. In the present embodiment, the sidewall 120S of the staircase structure 120 includes a sidewall of the insulating layer 121, a sidewall of the insulating layer 122, a sidewall of the insulating layer 123, a sidewall of the conductive layer 124, a sidewall of the conductive layer 125 and a sidewall of the conductive layer 126.

The conductive pillars 130 are disposed on the upper surface 120U of the staircase structure 120. The conductive pillars 130 can be separated from each other. The conductive pillars 130 are in the dielectric structure 150. The conductive pillars 130 can extend along the first direction D1 and penetrate the dielectric structure 150. The conductive pillars 130 can be disposed on (or contact) different conductive layers, and each conductive pillar 130 can be electrically connected to the conductive where it is located. For example, one conductive pillar 130 is disposed on the conductive layer 124 and electrically connected to the conductive layer 124, one conductive pillar 130 is disposed on the conductive layer 125 and electrically connected to the conductive layer 125, and one conductive pillar 130 is disposed on the conductive layer 126 and electrically connected to the conductive layer 126. Each conductive pillar 130 can be electrically connected to the conductive layer where it is located, and be electrically isolated from other conductive layers. For example, the conductive pillar 130 located on and electrically connected to the conductive layer 124 can be electrically isolated from the conductive layer 125 and the conductive layer 126, the conductive pillar 130 located on and electrically connected to the conductive layer 125 can be electrically isolated from the conductive layer 124 and the conductive layer 126, and the conductive pillar 130 located on and electrically connected to the conductive layer 126 can be electrically isolated from the conductive layer 124 and the conductive layer 125. The conductive pillar 130 has a columnar shape. A cross-section of the conductive pillar 130 on a plane formed by the second direction D2 and the third direction D3 can have any shape. For example, the cross-section of the conductive pillar 130 on a plane formed by the second direction D2 and the third direction D3 has a circular, elliptical, square, rectangular or polygonal shape.

The insulating films 160 are disposed on the upper surface 120U of the staircase structure 120. The insulating films 160 are in the dielectric structure 150. The insulating films 160 can extend along the first direction D1 and penetrate the dielectric structure 150. The insulating film 160 can be on an outer surface 130S of the conductive pillar 130. The insulating film 160 can surround the conductive pillar 130. The insulating films 160 can be disposed on (or contact) different conductive layers. The insulating film 160 may have a tubular shape or a hollow columnar shape.

The insulating structures 140 are in the staircase structure 120. The insulating structures 140 can penetrate the staircase structure 120 and be connected to the conductive pillars 130. The insulating structures 140 can be disposed below the conductive pillars 130. The insulating structure 140 can be between the substrate 110 and the conductive pillar 130. The insulating structure 140 includes an insulating pillar 141 and one or more insulating elements 142. The insulating element 142 is disposed on an outer surface 141S of the insulating pillar 141. The insulating element 142 protrudes from the outer surface 141S of the insulating pillar 141. The insulating element 142 may surround the insulating pillar 141, as shown in FIG. 1A. The insulating elements 142 are disposed separately on the outer surface 141S of the insulating pillar 141. The insulating pillar 141 can extend extends from the upper surface 110U of the substrate 110 to a lower surface 130L of the conductive pillar 130 along the first direction D1. Each insulating element 142 may adjoin one insulating layer in the second direction D2 and the third direction D3, and this insulating layer and the insulating element 142 are at the same level (that is, the height of this insulating layer in the first direction D1 is the same as the height of the insulating element 142 in the first direction D1). The insulating element 142 can be between two adjacent conductive layers in the first direction D1. For example, the insulating element 142 can be between the conductive layer 124 and the conductive layer 125, the insulating element 142 can be between the conductive layer 125 and the conductive layer 126. The insulating element 142 can be between the conductive layer 124 and the substrate 110. The conductive layers 24~126 can isolate the insulating elements 142 from the conductive pillars 130. The insulating elements are separated from each other by the conductive layers 124~126. The insulating pillar 141 has a columnar shape. The insulating element 142 has a ring shape.

The conductive pillar 130 is electrically isolated from one or more conductive layers below the conductive layer where this conductive pillar 130 is located by the insulating structure 140. For example, the conductive pillar 130 located on the conductive layer 125 is electrically isolated from the conductive layer 124 by the insulating structure 140, the conductive pillar 130 located on the conductive layer 126 is electrically isolated from the conductive layer 125 and the conductive layer 124 by the insulating structure 140. Providing the insulating structure 140 can ensure that the conductive pillar 130 is electrically connected to the target conductive layer and is not electrically connected to non-target conductive layer(s).

In an embodiment, an area of the insulating pillar 141 on a plane formed by the second direction D2 and the third direction D3 is smaller than an area of the conductive pillar 130 on a plane formed by the second direction D2 and the third direction D3. In an embodiment, a width W1 of the insulating pillar 141 in the second direction D2 is smaller than a width W2 of the conductive pillar 130 in the second direction D2. In an embodiment, a width of the insulating pillar 141 in the third direction D3 is smaller than a width of the conductive pillar 130 in the third direction D3. In an embodiment, a width W3 of the insulating film 160 in the second direction D2 is equal to or substantially equal to a width W4 of the insulating element 142 in the second direction D2.

In an embodiment, the semiconductor structure 10 can be used in a staircase region of a memory device. In an embodiment, the conductive layers 124~126 can be functioned as word lines of a memory device, and the conductive pillars 130 can be functioned as word line contact structures of a memory device.

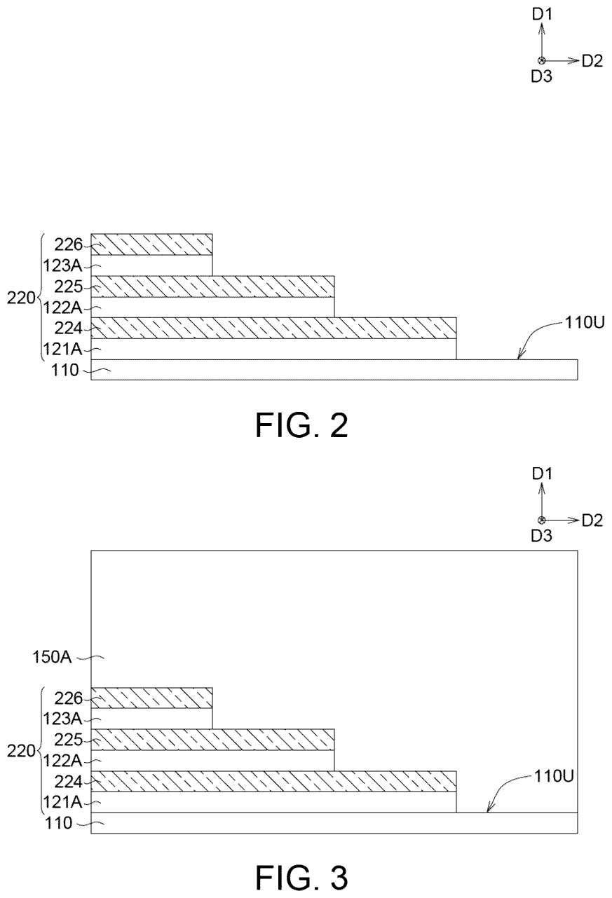

FIG. 2 to FIG. 9 illustrate a method for manufacturing a semiconductor structure according to some embodiments of the present disclosure.

Referring to FIG. 2, FIG. 2 shows a schematic cross-sectional view of the structure at one stage of the method for manufacturing the semiconductor structure. A substrate 110 is provided. An insulating staircase structure 220 is formed on the substrate 110. The insulating staircase structure 220 includes first insulating layers 121A, 122A and 123A and second insulating layers 224~226 stacked alternately along the first direction D1. The second insulating layers 224~226 are separated from each other by the first insulating layers 121A~123A. The first insulating layers 121A~123A and the second insulating layers 224~226 can extend along the second direction D2 and the third direction D3. The first insulating layers 121A~123A can have different sizes; the sizes of the first insulating layers 121A~123A are, for example, the areas on a plane formed by the second direction D2 and the third direction D3 (or can be understood as cross-sectional areas), or widths in the second direction D2 (or can be understood as lateral widths), or widths in the third direction D3 (or can be understood as lateral widths). The second insulating layers 224~226 can have different sizes; the sizes of the second insulating layers 224~226 are, for example, the areas on a plane formed by the second direction D2 and the third direction D3 (or can be understood as cross-sectional areas), or widths in the second direction D2 (or can be understood as lateral widths), or widths in the third direction D3 (or can be understood as lateral widths). For example, the cross-sectional areas of the second insulating layers 224~226 becomes smaller along the direction away from the substrate 110. For example, a cross-sectional area of the second insulating layer 224 at a lower level (a level closer to the substrate 110) is larger than a cross-sectional area of the second insulating layer 225 at an upper level (a level farther from the substrate 110).

The substrate 110 can be a semiconductor substrate. The substrate 110 can include a semiconductor material, such as doped or undoped monocrystalline silicon, doped or undoped polycrystalline silicon, or germanium. The materials of the first insulating layers 121A~123A can be different from the materials of the second insulating layers 224~226. The first insulating layers 121A~123A may include insulating materials, such as oxide. The second insulating layers 224~226 may include insulating materials, such as nitride. In an embodiment, the first insulating layers 121A~123A include or consist of high through put oxide to facilitate the formation of a large number of first insulating layers. In an embodiment, the first insulating layers 121A~123A include or consist of low dielectric constant oxide. In an embodiment, the first insulating layers 121A~123A include silicon oxide. In an embodiment, the second insulating layers 224~226 include silicon nitride. The first insulating layers 121A~123A and the second insulating layers 224~226 can be formed alternately on an upper surface 110U of the substrate 110 through a deposition process to form the insulating staircase structure 220.

Referring to FIG. 3, FIG. 3 shows a schematic cross-sectional view of the structure at one stage of the method for manufacturing the semiconductor structure. A dielectric structure 150A is formed on the insulating staircase structure 220. The dielectric structure 150A is on the substrate 110 and the insulating staircase structure 220. The dielectric structure 150A can cover a portion of the upper surface 110U of the substrate 110, an upper surface 220U of the insulating staircase structure 220, and a sidewall 220S of the insulating staircase structure 220. In the present embodiment, the upper surface 220U of the insulating staircase structure 220 includes the upper surfaces of the second insulating layers 224~226. In the present embodiment, the sidewall 220S of the insulating staircase structure 220 includes sidewalls of the second insulating layers 224~226, and sidewalls of the first insulating layers 121A~123A. The dielectric structure 150A may contact the insulating staircase structure 220 and the substrate 110. The dielectric structure 150A may include or consist of a dielectric material, such as oxide. For example, the oxide which can be used in the dielectric structure 150A is low density oxide, porous oxide or low dielectric constant oxide. In an embodiment, the dielectric structure 150A includes silicon oxide. In an embodiment, the dielectric structure 150A and the first insulating layers 121A~123A consist of different materials; for example, the density of oxide of the dielectric structure 150A is lower than the density of oxide of the first insulating layers 121A~123A, or the dielectric constant of oxide of the dielectric structure 150A is lower than the dielectric constant of oxide of the first insulating layers 121A~123A. In an embodiment, the dielectric structure 150A and the first insulating layers 121A~123A include the same material. The dielectric structure 150A can be formed on the substrate 110 and the insulating staircase structure 220 by a deposition process and a polishing process.

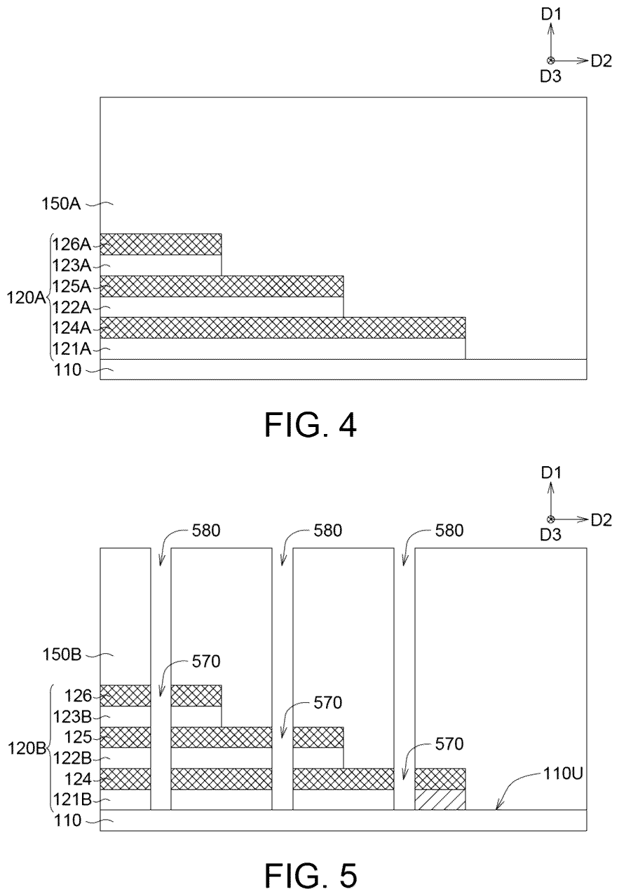

Referring to FIG. 4, FIG. 4 shows a schematic cross-sectional view of the structure at one stage of the method for manufacturing the semiconductor structure. A staircase structure 120A is formed. The dielectric structure 150A is on the staircase structure 120A. The staircase structure 120A includes conductive layers 124A~126A and the first insulating layers 121A~123A stacked alternately along the first direction D1. The conductive layers 124A~126A are between the first insulating layers 121A~123A. The conductive layers 124A~126A can extend along the second direction D2 and the third direction D3. The second insulating layers 224~226 of the insulating staircase structure 220 shown in FIG. 3 are replaced by the conductive layers 124A~126A respectively, thereby forming the staircase structure 120A. The conductive layers 124A~126A can include conductive materials, such as doped or undoped polycrystalline silicon, metal, titanium nitride or combinations thereof. The conductive layers 124A~126A can include combinations of conductive materials and high dielectric constant materials. The conductive layers 124A~126A can include multilayer structures, such as multilayer structures formed by conductive materials, or multilayer structures formed by one or more conductive materials and one or more high dielectric constant dielectric layers. The high dielectric constant material refers to a material with a dielectric constant larger than 3.9. The high dielectric constant material can be, but is not limited to, AlOₓ, Si₃N₄, La₂O₃, Ta₂O₅, Y₂O₃, TiO₂, HfOₓ, or ZrOₓ, x is larger than 0. In an embodiment, the conductive layers 124A~126A include AlOₓ/TiN/W multilayer structures. The staircase structure 120A can be formed by removing the second insulating layers 224~226 between the first insulating layers 121A~123A through an etching process, and then forming conductive layers 124A~126A between the first insulating layers 121A~123A through a deposition process.

Referring to FIG. 5, FIG. 5 shows a schematic cross-sectional view of the structure at one stage of the method for manufacturing the semiconductor structure. Holes 570 and holes 580 are formed. The holes 570 can be separated from each other. The holes 570 can extend along the first direction D1 and penetrate the staircase structure 120B. The upper surface 110U of the substrate 110, the sidewalls of the insulating layers 121B~123B, and sidewalls of the conductive layers 124~126 are exposed by the holes 570. The holes 580 can be separated from each other. The holes 580 can extend along the first direction D1 and penetrate the dielectric structure 150B. The sidewalls of the dielectric structure 150B are exposed by the holes 580. The holes 580 are above the holes 570. The holes 570 and the holes 580 may have a one-to-one correspondence; that is, the number of the holes 570 can be equal to the number of the holes 580, and each hole 570 at least partially overlaps the corresponding hole 580 in the first direction D1. The hole 570 can be connected to (or communicate with) the corresponding hole 580. The area of the hole 570 on a plane formed by the second direction D2 and the third direction D3 (or can be understood as cross-sectional areas) may be equal to the area of the hole 580 on a plane formed by the second direction D2 and the third direction D3 (or can be understood as cross-sectional areas). The hole 570 has a columnar shape. The hole 580 has a columnar shape. The cross-sections of the hole 570 and the hole 580 on a plane formed by the second direction D2 and the third direction D3 can have any shape. For example, the cross-sections of the hole 570 and the hole 580 on a plane formed by the second direction D2 and the third direction D3 have circular, elliptical, square, rectangular or polygonal shapes. The holes 570 and the holes 580 can be formed by removing portions of the first insulating layers 121A~123A (as shown in FIG. 4), portions of the conductive layers 124A~126A (as shown in FIG. 4), and a portion of the dielectric structure 150A (as shown in FIG. 4) through an etching process. The retained portions of the first insulating layers 121A~123A are the insulating layers 121B~123B. The retained portions of the conductive layers 124A~126A are the conductive layers 124~126. The staircase structure 120B includes the insulating layers 121B~123B and the conductive layers 124~126. The retained portion of the dielectric structure 150A is the dielectric structure 150B. The etching process used to form the holes 570 can stop at the upper surface 110U of the substrate 110.

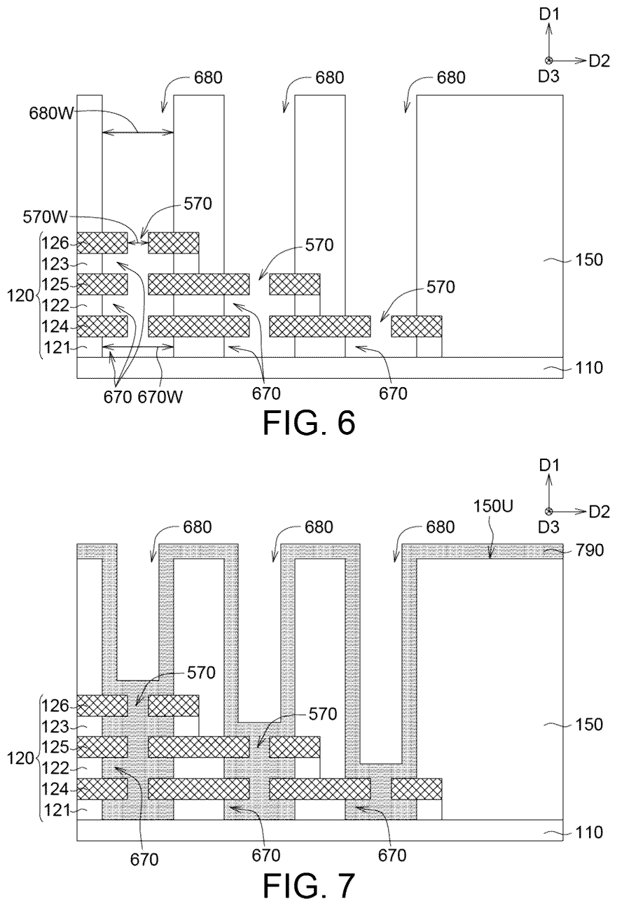

Referring to FIG. 6, FIG. 6 shows a schematic cross-sectional view of the structure at one stage of the method for manufacturing the semiconductor structure. Recesses 670 are formed. Holes 680 are formed. The recesses 670 are separated from each other and disposed in the staircase structure 120. The recess 670 surround the hole 570. The recess 670 is connected to (or communicate with) the hole 570 surrounded by itself. The recesses 670 connected to the same hole 570 can be disposed along the first direction D1. The recesses 670 are separated from each other by the conductive layers 124~126. The recess 670 can have an annular shape. The upper surfaces of the conductive layers 124~126, the lower surfaces of the conductive layers 124~126, and the sidewalls of the insulating layers 121~123 are exposed by the recesses 670. The recess 670 can be between two adjacent conductive layers in the first direction D1. For example, the recess 670 can be between the conductive layer 126 and the conductive layer 125 adjacent to the conductive layer 126 in the first direction D1; the recess 670 can be between the conductive layer 125 and the conductive layer 124 adjacent to the conductive layer 125 in the first direction D1. The recess 670 can be disposed between the conductive layer 124 and the substrate 110.

The holes 680 are separated from each other and disposed in the dielectric structure 150. The holes 680 can extend along the first direction D1 and penetrate the dielectric structure 150. The sidewalls of the dielectric structure 150 are exposed by the holes 680. The upper surfaces of the conductive layers 124~126 are exposed by the holes 680. The hole 680 can be above the hole 570. The holes 680 and the holes 570 may have a one-to-one correspondence; that is, the number of the holes 680 can be equal to the number of the holes 570, and each hole 680 overlaps the corresponding hole 570 in the first direction D1. The hole 680 can be connected to (or communicate with) the corresponding hole 570. The hole 680 has a columnar shape. The cross-section of the hole 680 on a plane formed by the second direction D2 and the third direction D3 can have any shape. For example, the cross-section of the hole 680 on a plane formed by the second direction D2 and the third direction D3 has a circular, elliptical, square, rectangular or polygonal shape. In an embodiment, a width 680W of the hole 680 in the second direction D2 is larger than a width 570W of the hole 570 in the second direction D2. In an embodiment, a width of the hole 680 in the third direction D3 is larger than a width of the hole 570 in the third direction D3. The width of the hole 680 in the second direction D2 and the width of the hole 680 in the third direction D3 can be understood as lateral widths. In an embodiment, the width 680W of the hole 680 in the second direction D2 is equal to or substantially equal to a width 670W of the recess 670 in the second direction D2. In an embodiment, the width 570W of the hole 570 is the maximum lateral width of hole 570. In an embodiment, the width 670W of the recess 670 is the maximum lateral width of recess 670. In an embodiment, the width 680W of the hole 680 is the maximum lateral width of the hole 680.

Portions of the insulating layers 121B~123B (as shown in FIG. 5) of the staircase structure 120B can be removed through an etching process to form recesses 670 in the staircase structure 120. The retained portions of the insulating layers 121B~123B are the insulating layers 121~123. The staircase structure 120 includes the insulating layers 121~123 and the conductive layers 124~126. A portion of the dielectric structure 150B (as shown in FIG. 5) can be removed through an etching process to form holes 680 above the staircase structure 120. The retained portion of the dielectric structure 150B is the dielectric structure 150. In an embodiment, the etching processes used to form the recesses 670 and the holes 680 are isotropic etching processes. In an embodiment, portions of the insulating layers 121B~123B of the staircase structure 120B can be removed through the holes 570 to form the recesses 670. In an embodiment, a portion of the dielectric structure 150B can be removed through the holes 580 to form the holes 680.

Referring to FIG. 7, FIG. 7 shows a schematic cross-sectional view of the structure at one stage of the method for manufacturing the semiconductor structure. A insulating material 790 is formed. A portion (first portion) of the insulating material 790 can be formed in the recesses 670 and the holes 570, a portion (second portion) of the insulating material 790 can be formed in the holes 680, and a portion (third portion) of the insulating material 790 can be formed on the upper surface 150U of the dielectric structure 150. The first portion of the insulating material 790 may fill the recesses 670 and the holes 570. The second portion of insulating material 790 may occupy portions of the spaces of holes 680. The second portion of insulating material 790 may be formed on the sidewalls of the dielectric structure 150 exposed by the holes 680, and the upper surfaces of the conductive layers 124~126 exposed by the holes 680. The insulating material 790 can includes oxide or other insulating material. For example, the insulating material 760 can include or can be aluminum oxide (Al₂O₃), hafnium dioxide (HfO₂), silicon oxide (SiO₂), or titanium oxide (TiO₂). The insulating material 790 can be formed in the recesses 670, the holes 570 and the holes 680 through a deposition process. In an embodiment, the insulating material 790 is formed by a highly conformal deposition process. In an embodiment, the deposition process used to form the insulating material 790 is an atomic layer deposition process.

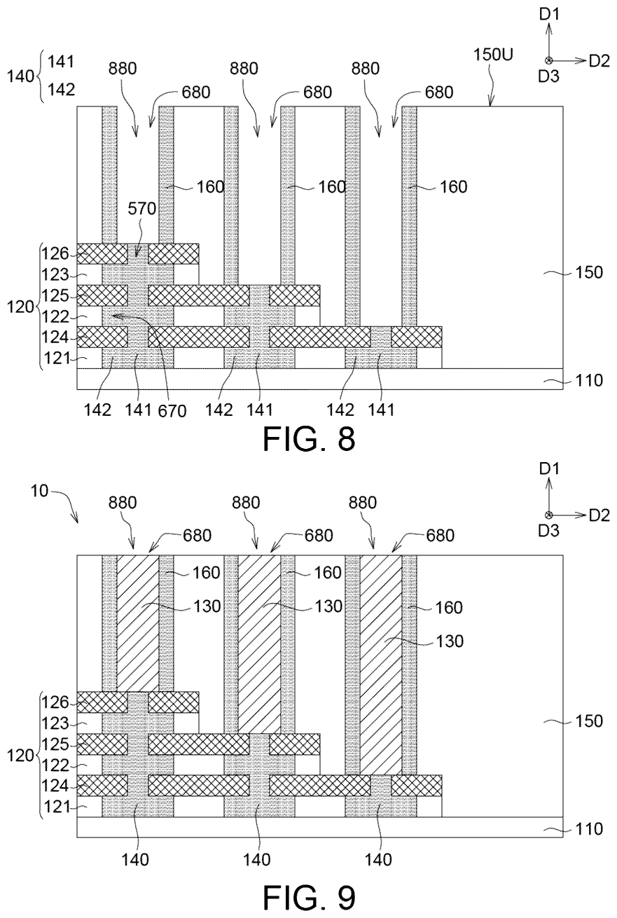

Referring to FIG. 8, FIG. 8 shows a schematic cross-sectional view of the structure at one stage of the method for manufacturing the semiconductor structure. Insulating structures 140 and insulating films 160 are formed. The insulating structures 140 are disposed in the staircase structure 120. The insulating films 160 are disposed above the staircase structure 120. The insulating films 160 may contact the conductive layers 124~126 and the dielectric structure 150. The insulating structures 140 may have different heights in the first direction D1. For example, the upper surface of one insulating structure 140 and the upper surface of the conductive layer 126 may have the same height in the first direction D1; the upper surface of another insulating structure 140 and the upper surface of the conductive layer 125 may have the same height in the first direction D1; the upper surface of another insulating structure 140 and the upper surface of the conductive layer 124 may have the same height in the first direction D1. The upper surface of the insulating structure 140 and the upper surface of the staircase structure 120 can be coplanar. The insulating structure 140 may be separated from the insulating film 160. An etching process can be performed to remove a portion of the insulating material 790 (as shown in FIG. 7) on the upper surface of the staircase structure 120 and a portion of the insulating material 790 on the upper surface 150U of the dielectric structure 150, while retain portions of the insulating material 790 in the recesses 670, portions of the insulating material 790 in the holes 570, and portions of the insulating material 790 on the sidewalls of the dielectric structure 150 exposed by the holes 680. The portions of the insulating material 790 in the recesses 670 are insulating elements 142. The portions of the insulating material 790 in the holes 570 are insulating pillars 141. The insulating structure 140 can include the insulating pillar 141 and one or more insulating elements 142 surrounding this insulating pillar 141. The portions of the insulating material 790 on the sidewalls of the dielectric structure 150 exposed by the holes 680 are insulating films 160. At the present stage, the remaining spaces of the holes 680 (that is, the spaces not occupied by the insulating films 160) are the spaces 880. The space 880 can be surrounded by the insulating film 160. In an embodiment, the etching process for forming the insulating structures 140 and the insulating films 160 is a reactive ion etching (RIE) process. The insulating film 160, the insulating pillar 141 and the insulating element 142 may include the same material. The insulating film 160, the insulating pillar 141 and the insulating element 142 may be made of the same material.

Referring to FIG. 9, FIG. 9 shows a schematic cross-sectional view of the structure at one stage of the method for manufacturing the semiconductor structure. Conductive pillars 130 are formed above the staircase structure 120 and the insulating structures 140. The conductive pillar 130 can contact the insulating film 160. The conductive pillars 130 are disposed in the spaces 880. The conductive pillars 130 are disposed on the upper surfaces of the conductive layers 124~126 exposed by the spaces 880 (or the upper surfaces of the conductive layers 124~126 exposed by the holes 680). The conductive pillars 130 can be electrically connected to the conductive layers 124~126 exposed by the space 880 (or the conductive layers 124~126 exposed by he holes 680). The conductive pillar 130 may include a conductive material, such as tungsten. The conductive pillars 130 can be formed in the spaces 880 through a deposition process.

In an embodiment, through the method schematically illustrated in FIGS. 2 to 9, a semiconductor structure 10 as shown FIG. 1 is provided.

In the semiconductor structure and the method for manufacturing the same according to the present disclosure, the insulating structure penetrates the staircase structure and is connected to the conductive pillar, and the etching process used to form the conductive pillar can proceed through the staircase structure (e.g. the steps shown in FIGS. 5 and 6) without stopping on a specific conductive layer, which can avoid the problem of conductive pillars electrically connecting to unintended conductive layer caused by over-etching, and can improve the electrical performance of the semiconductor structure. The configuration of the present disclosure can avoid the short circuit problem caused by the electrical connection of the conductive pillar to the unintended conductive layer. Moreover, the present disclosure does not need to increase the thickness of the conductive layer (for example, the thickness in the first direction D1) to avoid the over-etching. Therefore, the present disclosure can improve the problem of difficult control of etching while maintaining a thin conductive layer, and can ensure both the electrical performance and size miniaturization of semiconductor structures.

It is noted that the structures and methods as described above are provided for illustration. The disclosure is not limited to the configurations and procedures disclosed above. Other embodiments with different configurations of known elements can be applicable, and the exemplified structures could be adjusted and changed based on the actual needs of the practical applications. It is, of course, noted that the configurations of figures are depicted only for demonstration, not for limitation. Thus, it is known by people skilled in the art that the related elements and layers in a semiconductor structure, the shapes or positional relationship of the elements and the procedure details could be adjusted or changed according to the actual requirements and/or manufacturing steps of the practical applications.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor structure, comprising:
a staircase structure comprising conductive layers and insulating layers stacked alternately;
a conductive pillar on the staircase structure; and
an insulating structure penetrating the staircase structure and connected to the conductive pillar.

2. The semiconductor structure according to claim 1, wherein the insulating structure comprises an insulating pillar and an insulating element disposed on an outer surface of the insulating pillar and protrudes from the outer surface of the insulating pillar.

3. The semiconductor structure according to claim 2, wherein the conductive layers isolate the insulating element from the conductive pillar.

4. The semiconductor structure according to claim 2, wherein the insulating element surrounds the insulating pillar.

5. The semiconductor structure according to claim 2, further comprising an insulating film surrounding the conductive pillar, wherein the insulating film, the insulating pillar and the insulating element comprise the same material.

6. The semiconductor structure according to claim 5, wherein the conductive layers and the insulating layers are disposed along a first direction, the insulating film has a width along a second direction perpendicular to the first direction, the insulating element has a width along the second direction, and the width of the insulating film is equal to or substantially equal to the width of the insulating element.

7. The semiconductor structure according to claim 2, further comprising a substrate, wherein the staircase structure is on an upper surface of the substrate, and the insulating pillar extends from the upper surface of the substrate to a lower surface of the conductive pillar.

8. The semiconductor structure according to claim 1, wherein the insulating structure comprises an insulating pillar and insulating elements disposed separately on an outer surface of the insulating pillar.

9. The semiconductor structure according to claim 8, wherein the insulating elements are separated from each other by the conductive layers.

10. The semiconductor structure according to claim 1, wherein the conductive pillar is disposed on and electrically connected to a conductive layer of the conductive layers.

11. The semiconductor structure according to claim 10, wherein the conductive pillar is electrically isolated from the other conductive layers of the conductive layers.

12. The semiconductor structure according to claim 10, wherein the conductive pillar is electrically isolated from one or more conductive layers of the conductive layers below the conductive layer.

13. A method for manufacturing a semiconductor structure, comprising:
forming a staircase structure, wherein the staircase structure comprises conductive layers and insulating layers stacked alternately;
forming an insulating structure penetrating the staircase structure; and
forming a conductive pillar on the staircase structure.

14. The method according to claim 13, further comprising:
forming a first hole penetrating the staircase structure; and
forming a recess surrounding the first hole in the staircase structure, wherein the recess is connected to the first hole.

15. The method according to claim 14, wherein an upper surface of the conductive layers, a lower surface of the conductive layers, and a sidewall of the insulating layers are exposed by the recess.

16. The method according to claim 14, wherein the conductive layers and the insulating layers are disposed along a first direction, the conductive layers comprises a first conductive layer and a second conductive layer adjacent to the first conductive layer along the first direction, and the recess is between the first conductive layer and the second conductive layer.

17. The method according to claim 14, further comprising:
forming an insulating material in the first hole and the recess to form the insulating structure.

18. The method according to claim 13, further comprising:
forming a dielectric structure on the staircase structure;
forming a first hole penetrating the staircase structure; and
forming a recess surrounding the first hole in the staircase structure, wherein the recess is connected to the first hole; and
forming a second hole penetrating the dielectric structure, wherein the first hole is connected to the second hole, and a width of the second hole is larger than a width of the first hole.

19. The method according to claim 18, further comprising:
providing a substrate,
wherein the staircase structure is formed on the substrate,
an upper surface of the substrate is exposed by the first hole, a sidewall of the dielectric structure and an upper surface of a conductive layer of the conductive layers of the staircase structure are exposed by the second hole.

20. The method according to claim 19, further comprising:
forming an insulating material in the first hole and the recess to form the insulating structure;
forming the insulating material and a conductive material in the second hole to form an insulating film and the conductive pillar, wherein the insulating film surrounds the conductive pillar, and the conductive pillar is electrically connected to the conductive layer exposed by the second hole.
